(19) United States
(12) Patent Application Publication
(10) Pub. No.: US 2008/0164605 A1
(43) Pub. Date: Jul. 10, 2008

(54) MULTI-CHIP PACKAGE

(75) Inventor: PING-CHANG WU, HSINCHU COUNTY (TW)

Correspondence Address: J C PATENTS, INC., 4 VENTURE, SUITE 250, IRVINE, CA, 92618, US

(73) Assignee: UNITED MICROELECTRONICS CORP., HSINCHU (TW)

(21) Appl. No.: 11/620,992

(22) Filed: Jan. 8, 2007

(51) Int. Cl. H01L 23/50

(52) U.S. Cl. 257/723; 257/E23.079

(57) ABSTRACT

A multi-chip package including a substrate, a first chip, a plurality of conductive bodies, a second chip, and a plurality of conductive studs is provided. The substrate has a first surface. The first chip disposed on the first surface has a first orthogonal projection on the first surface. The conductive bodies are disposed and electrically connected between the first chip and the first surface. The second chip disposed on the first surface has a second orthogonal projection on the first surface. At least part of the first chip is between the second chip and the substrate. The first orthogonal projection at least overlaps the second orthogonal projection. The conductive studs are disposed and electrically connected between the second chip and the first surface.

### BACKGROUND OF THE INVENTION

1. Field of the Invention

The present invention relates to a semiconductor device, and more particularly to a multi-chip package.

2. Description of Related Art

In the fabrication of semiconductor devices, the manufacturing of integrated circuits (IC) is mainly divided into three stages, namely, the IC design stage, the IC processing stage and the IC packaging stage.

In the processing of IC, a chip is fabricated by going through a series of steps including wafer fabrication, formation of integrated circuits on the wafer and sawing of the wafer. A wafer has an active surface, commonly referring to the surface of the wafer with active elements. When the fabrication of IC on the wafer is complete, a plurality of bonding pads is disposed on the active surface of the wafer so that the chip cut out after a wafer sawing process can electrically connect with a carrier through the bonding pads. The carrier is, for example, a leadframe or a package substrate. The chip may be electrically connected to the carrier using wire bonding or flip-chip bonding method so that the bonding pads on the chip can be electrically connected to the contacts on the carrier to form a chip package structure.

When flip-chip bonding technology is used, a solder bump is normally fabricated on each bonding pad to serve as medium for electrically connecting to an external package substrate after the bonding pads are formed on the active surface of the wafer. Because these solder bumps are arranged to form an array on the active surface of the chip, the flip-chip bonding technology is particularly suitable for applications involving a large number of contacts and high contact density on a chip package. For example, the flip chip/ball grid array package is now commonly used in the semiconductor packaging industry. In addition, compared with the wire bonding technology, the solder bumps can provide shorter transmission paths between the chip and the carrier so that the flip-chip bonding technology is able to improve overall electrical performance of the chip package.

However, with the goals of optimizing the electrical performance, lowering the production cost and increasing the level of integration of IC devices, the conventional single chip package structure can no longer meet the requirements of the electronic industry. Therefore, using either the wire bonding or the flip-chip bonding technology, ways of stacking up a number of chips have been developed to form a multi-chip package structure.

In the conventional technology, the chips in the multi-chip package use either bonding wires or solder bumps as the electrical connection medium for connecting with the substrate. However, there is a definite limitation on the density of the wires and the transmission path through a wire is slightly longer. In addition, with the increasing height of electrical connection between the chip and the substrate, the volume occupied by the solder bumps also increases correspondingly. Therefore, as a whole, regardless of whether wires or solder bumps are used as an electrical connection medium, the multi-chip package produced by the conventional technology occupies a larger volume.

### SUMMARY OF THE INVENTION

The present invention is to provide a multi-chip package that occupies a smaller volume.

The present invention is to provide a multi-chip package with an internal chip whose contacts have a higher density.

The present invention provides a multi-chip package comprising a substrate, a first chip, a plurality of conductive bodies, a second chip and a plurality of conductive studs. The substrate has a first surface. The first chip disposed on the first surface has a first orthogonal projection on the first surface. The conductive bodies are disposed and electrically connected between the first chip and the first surface. The second chip disposed on the first surface has a second orthogonal projection on the first surface. At least part of the first chip is between the second chip and the substrate. Furthermore, the first orthogonal projection at least overlaps the second orthogonal projection. The conductive studs are disposed and electrically connected between the second chip and the first surface.

In an embodiment of the present invention, the foregoing substrate may include a cavity on the first surface, wherein the first chip is located.

In an embodiment of the present invention, the material of the foregoing conductive studs is selected from a group comprising copper, aluminum, gold, platinum and titanium or one of the alloys formed by combining at least one of the materials in the group, for example.

In an embodiment of the present invention, the foregoing conductive bodies may be conductive bumps.

In an embodiment of the present invention, the foregoing conductive bodies can have a shape identical to the conductive studs. In addition, the material of the conductive bodies is selected from a group comprising copper, aluminum, gold, platinum and titanium or one of the alloys formed by combining at least one of the materials in the group, for example.

In an embodiment of the present invention, the foregoing multi-chip package further includes an adhesive layer disposed between the first chip and the second chip.

In an embodiment of the present invention, the foregoing multi-chip package further includes an underfill layer at least encapsulating the conductive bodies and the conductive studs.

In an embodiment of the present invention, the foregoing multi-chip package further includes a plurality of solder balls disposed on a second surface of the substrate on the opposite side of the first surface.

The present invention also provides another multi-chip package. The multi-chip package includes a substrate, a first chip, a plurality of conductive bodies, a second chip, a plurality of first conductive studs, a third chip and a plurality of second conductive studs. The substrate has a first surface. The first chip disposed on the first surface has a first orthogonal projection on the first surface. The conductive bodies are disposed and electrically connected between the first chip and the first surface. The second chip disposed on the first surface has a second orthogonal projection on the first surface. At least part of the first chip is between the second chip and the substrate. Furthermore, the first orthogonal projection at least overlaps the second orthogonal projection. The first conductive studs are disposed and electrically connected between the second chip and the first surface. The third chip disposed on the first surface has a third orthogonal projection on the first surface. At least part of the second chip is between the third chip and the substrate. Furthermore, the second orthogonal projection at least overlaps the third orthogonal projection. The second conductive studs are disposed and electrically connected between the third chip and the first surface.

In an embodiment of the present invention, the foregoing substrate may include a cavity on the first surface, wherein the first chip is located.

In an embodiment of the present invention, the material of the foregoing first conductive studs is selected from a group comprising copper, aluminum, gold, platinum and titanium or one of the alloys formed by combining at least one of the materials in the group, for example.

In an embodiment of the present invention, the material of the foregoing second conductive studs is selected from a group comprising copper, aluminum, gold, platinum and titanium or one of the alloys formed by combining at least one of the materials in the group, for example.

In an embodiment of the present invention, the foregoing conductive bodies may be conductive bumps.

In an embodiment of the present invention, the foregoing conductive bodies can have a shape identical to the first conductive studs or the second conductive studs. In addition, the material of the conductive bodies is selected from a group comprising copper, aluminum, gold, platinum and titanium or one of the alloys formed by combining at least one of the materials in the group, for example.

In an embodiment of the present invention, the foregoing multi-chip package further includes a first adhesive layer disposed between the first chip and the second chip.

In an embodiment of the present invention, the foregoing multi-chip package further includes a second adhesive layer disposed between the second chip and the third chip.

In an embodiment of the present invention, the foregoing multi-chip package further includes an underfill layer at least encapsulating the conductive bodies, the first conductive studs and the second conductive studs.

In an embodiment of the present invention, the foregoing multi-chip package further includes a plurality of solder balls disposed on a second surface of the substrate on the opposite side of the first surface.

The present invention also provides yet another multi-chip package. The multi-chip package includes a substrate, a first chip, a second chip, a plurality of first conductive bodies and a plurality of first conductive studs. The substrate has a first surface. The first chip disposed on the first surface has a first orthogonal projection on the first surface. The second chip disposed on the first surface has a second orthogonal projection on the first surface. At least part of the first chip is between the second chip and the substrate. Furthermore, the first orthogonal projection at least overlaps the second orthogonal projection. The first conductive bodies are disposed and electrically connected between the first chip and the second chip. In addition, the first conductive studs are disposed and electrically connected between the second chip and the first surface.

In an embodiment of the present invention, the foregoing substrate may include a cavity on the first surface, wherein the first chip is located.

In an embodiment of the present invention, the material of the foregoing first conductive studs is selected from a group comprising copper, aluminum, gold, platinum and titanium or one of the alloys formed by combining at least one of the materials in the group, for example.

In an embodiment of the present invention, the foregoing first conductive bodies may be conductive bumps.

In an embodiment of the present invention, the foregoing first conductive bodies can have a shape identical to the first conductive studs or the second conductive studs. In addition, the material of the first conductive bodies is selected from a group comprising copper, aluminum, gold, platinum and titanium or one of the alloys formed by combining at least one of the materials in the group, for example.

In an embodiment of the present invention, the foregoing multi-chip package further includes an adhesive layer disposed between the first chip and the substrate.

In an embodiment of the present invention, the foregoing multi-chip package further includes an underfill layer at least encapsulating the first conductive bodies and the first conductive studs.

In an embodiment of the present invention, the foregoing multi-chip package further includes a plurality of solder balls disposed on a second surface of the substrate on the opposite side of the first surface.

In an embodiment of the present invention, the foregoing multi-chip package further includes a third chip, a plurality of second conductive bodies and a plurality of second conductive studs. The third chip disposed on the first surface has a third orthogonal projection on the first surface. At least part of the first chip is between the third chip and the substrate. Furthermore, the first orthogonal projection at least overlaps the third orthogonal projection. The second conductive bodies are disposed and electrically connected between the third chip and the first chip. The second conductive studs are disposed and electrically connected between the third chip and the first surface. The material of the foregoing second conductive studs may be selected from a group comprising copper, aluminum, gold, platinum and titanium or one of the alloys formed by combining at least one of the materials in the group, for example.

The present invention also provides yet another multi-chip package. The multi-chip package includes a substrate, a first chip, a plurality of first conductive bodies, a second chip, a plurality of second conductive bodies, a third chip and a plurality of conductive studs. The substrate has a first surface. The first chip disposed on the first surface has a first orthogonal projection on the first surface. The first conductive bodies are disposed and electrically connected between the first chip and the first surface. The second chip disposed on the first surface has a second orthogonal projection on the first surface. The second conductive bodies are disposed and electrically connected between the second chip and the first surface. The third chip disposed on the first surface has a third orthogonal projection on the first surface. The first chip and the second chip are between the third chip and the substrate. Furthermore, the third orthogonal projection at least overlaps the first chip and the second chip respectively. The conductive studs are electrically connected between the third chip and the first surface.

In an embodiment of the present invention, the foregoing substrate may include two cavities on the first surface, wherein the first chip and the second chip are located on the respective cavities.

In an embodiment of the present invention, the material of the foregoing conductive studs is selected from a group comprising copper, aluminum, gold, platinum and titanium or one of the alloys formed by combining at least one of the materials in the group, for example.

In an embodiment of the present invention, the foregoing first conductive bodies may be conductive bumps.

In an embodiment of the present invention, the foregoing first conductive bodies can have a shape identical to the conductive studs. In addition, the material of the first conductive bodies is selected from a group comprising copper, aluminum, gold, platinum and titanium or one of the alloys formed by combining at least one of the materials in the group, for example.

In an embodiment of the present invention, the foregoing second conductive bodies may be conductive bumps.

In an embodiment of the present invention, the foregoing second conductive bodies can have: a shape identical to the conductive studs. In addition, the material of the second conductive bodies is selected from a group comprising copper, aluminum, gold, platinum and titanium or one of the alloys formed by combining at least one of the materials in the group, for example.

In an embodiment of the present invention, the foregoing multi-chip package further includes an adhesive layer disposed between the third chip and the first chip and between the third chip and the second chip.

In an embodiment of the present invention, the foregoing multi-chip package further includes an underfill layer at least encapsulating the first conductive bodies, the second conductive bodies and the conductive studs.

In an embodiment of the present invention, the foregoing multi-chip package further includes a plurality of solder balls disposed on a second surface of the substrate on the opposite side of the first surface.

Accordingly, because at least one of the chips inside the multi-chip package of the present invention is electrically connected to the substrate through the conductive studs and each stud occupies only a relatively small volume, the multi-chip package occupies a volume smaller than the one fabricated by the conventional method.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view of a multi-chip package according to a first embodiment of the present invention.

FIG. 1B is a diagram showing orthogonal projections of the chips in FIG. 1A on a substrate.

FIG. 1C is a schematic cross-sectional view of another multi-chip package according to the first embodiment of the present invention.

FIG. 2A is a schematic cross-sectional view of a multi-chip package according to a second embodiment of the present invention.

FIG. 2B is a diagram showing orthogonal projections of the chips in FIG. 2A on a substrate.

FIG. 3A is a schematic cross-sectional view of a multi-chip package according to a third embodiment of the present invention.

FIG. 3B is a diagram showing orthogonal projections of the chips in FIG. 3A on a substrate.

FIG. 3C is a schematic cross-sectional view of another multi-chip package according to the third embodiment of the present invention.

FIG. 3D is a diagram showing orthogonal projections of the chips in FIG. 3C on a substrate.

FIG. 4A is a schematic cross-sectional view of a multi-chip package according to a fourth embodiment of the present invention.

FIG. 4B is a diagram showing orthogonal projections of the chips in FIG. 4A on a substrate.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

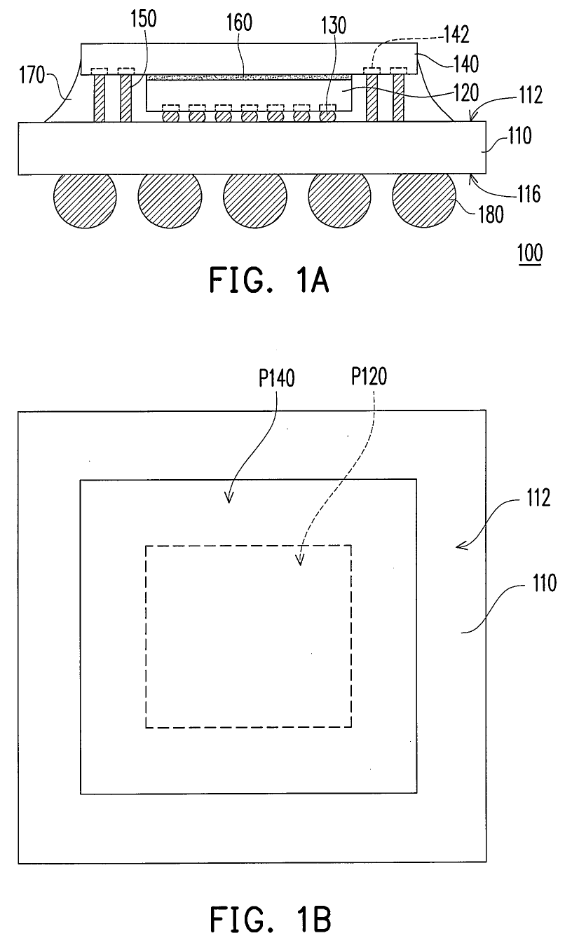

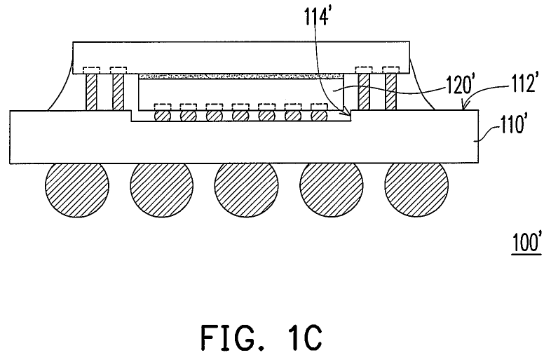

FIG. 1A is a schematic cross-sectional view of a multi-chip package according to a first embodiment of the present invention. FIG. 1B is a diagram showing orthogonal projections of the chips in FIG. 1A on a substrate. As shown in FIGS. 1A and 1B, the multi-chip package 100 of the first embodiment includes a substrate 110, a first chip 120, a plurality of conductive bodies 130, a second chip 140 and a plurality of conductive studs 150. The substrate 110 has a first surface 112. The first chip 120 disposed on the first surface 112 has a first orthogonal projection P120 on the first surface 112.

The conductive bodies 130 are disposed and electrically connected between the first chip 120 and the first surface 112. The second chip 140 disposed on the first surface 112 has a second orthogonal projection P140 on the first surface 112. At least part of the first chip 120 is between the second chip 140 and the substrate 110. Furthermore, the first orthogonal projection P120 at least overlaps the second orthogonal projection P140. In addition, the conductive studs 150 are disposed and electrically connected between the second chip 140 and the first surface 112.

Because the second chip 140 is electrically connected to the substrate 110 through the conductive studs 150 and each conductive stud 150 only occupies a very small space, the areas of the bonding pads 142 on the second chip 140 for contacting the corresponding conductive studs 150 may be smaller and the pitch between neighboring bonding pads 142 may be reduced. Therefore, compared with a multi-chip package formed by the conventional technology, the volume of the second chip 140 may be smaller when the second chip 140 in the multi-chip package 100 of the present embodiment has the same number of bonding pads 142. In other words, the multi-chip package 100 can occupy a smaller volume.

FIG. 1C is a schematic cross-sectional view of another multi-chip package according to the first embodiment of the present invention. To reduce the volume of the multi-chip package 100′ even further, the substrate 100′ may include a cavity 114′ on the first surface 112′ and the first chip 120′ is located inside the cavity 114′. With this characteristic setup, the length of the conductive studs 150 is reduced indirectly.

Again as shown in FIGS. 1A and 1B, the material of the conductive studs 150 in the first embodiment, for example, may be selected from a group comprising copper, aluminum, gold, platinum and titanium or one of the alloys formed by combining at least one of the materials in the group. Furthermore, the conductive bodies 130 in the first embodiment may be conductive bumps. The conductive bodies 130 may be fabricated from lead-containing material (for example, lead or lead-tin alloy) or leadless material including gold, copper, tin or nickel or an alloy or compound that contains gold, copper, tin or nickel. It should be noted that the shape of these conductive bodies 130 in the first embodiment might be identical to the conductive studs 150 (not drawn) in order to reduce the volume of the first chip 120. Meanwhile, the material constituting the conductive bodies 130 may also be identical to that of the conductive studs 150.

In the first embodiment, the multi-chip package 100 may also include an adhesive layer 160, an underfill layer 170 and a plurality of solder balls 180. The adhesive layer 160 is disposed between the first chip 120 and the second chip 140. The main function of the adhesive layer 160 is to attach the second chip 140 firmly to the first chip 120. In addition, the underfill layer 170 at least encapsulates the conductive bodies 130 and the conductive studs 150. In the first embodiment, the underfill layer 170 also encapsulates the first chip 120. The underfill layer 170 serves to protect the conductive bodies 130 and the conductive studs 150. Furthermore, when the multi-chip package 100 operates and generates heat, the underfill layer 170 may serve as a buffer for thermal strain mismatch between the heated substrate 110 and the heated first chip 120 as well as between the heated substrate 110 and the heated second chip 140.

The solder balls 180 are disposed on a second surface 116 of the substrate 110 on the opposite side of the first surface 112 for electrically connecting with other electronic devices (not shown). The solder balls 180 in the first embodiment may be arranged to form an array so as to provide a ball grid array (BGA) type of signal output interface. It should be noted that the solder balls 180 might be replaced by a plurality of conductive pins or a plurality of conductive columns to provide a pin grid array (PGA) type or a column grip array (CGA) type of signal output interface. However, the later two types are not shown with diagrams.

### Second Embodiment

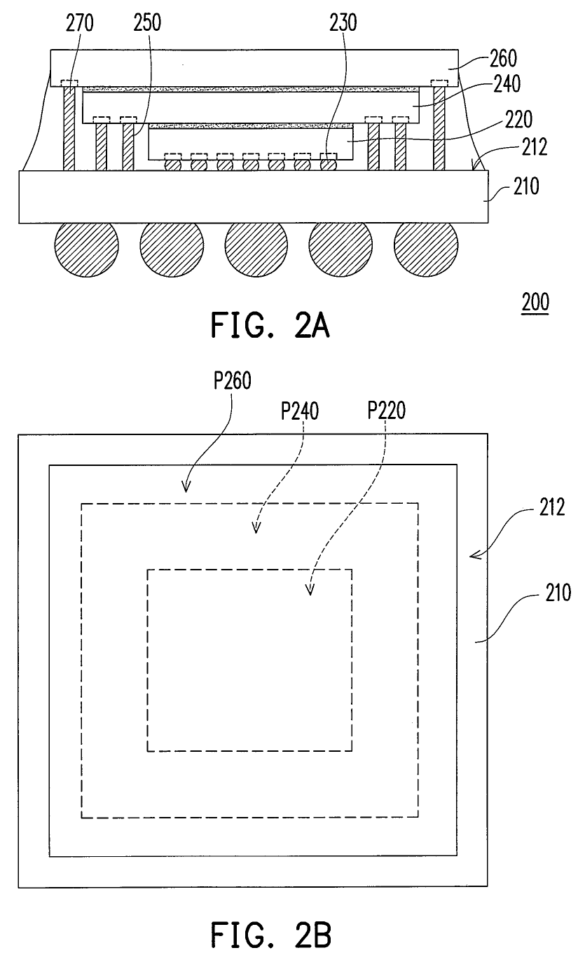

FIG. 2A is a schematic cross-sectional view of a multi-chip package according to a second embodiment of the present invention. FIG. 2B is a diagram showing orthogonal projections of the chips in FIG. 2A on a substrate. As shown in FIGS. 1A, 2A and 2B, the main difference between the multi-chip package 200 in the second embodiment and the multi-chip package 100 in the first embodiment is that the multi-chip package 200 includes a first chip 220, a second chip 240 and a third, chip 260.

More specifically at least part of the first chip 220 is between the second chip 240 and the substrate 210. Moreover, the first orthogonal projection P220 of the first chip 220 on the first surface 212 at least overlaps the second orthogonal projection P240 of the second chip 240 on the first surface 212. In addition, at least part of the second chip 240 is between the third chip 260 and the substrate 210. Furthermore, a third orthogonal projection P260 of the third chip 260 on the first surface 212 at least overlaps the second orthogonal projection P240. In the second embodiment, the first orthogonal projection P220 is located entirely within the second orthogonal projection P240, and the second orthogonal projection P240 is located entirely within the third orthogonal projection P260, for example. However, the package designers may modify the relative locations of the first chip 220, the second chip 240 and the third chip 260 according to the design requirements as long as the first orthogonal projection P220 at least overlaps the second orthogonal projection P240 and the third orthogonal projection P260 at least overlaps the second orthogonal projection P240.

In the second embodiment, the first conductive studs 250 are disposed and electrically connected between the second chip 240 and the first surface 212 of the substrate 210. The second conductive studs 270 are disposed and electrically connected the third chip 260 and the first surface 212 of the substrate 210. Furthermore, the conductive bodies 230 are disposed and electrically connected between the first chip 220 and the first surface 212. In addition, the shape, the material and the function of the first conductive studs 250 and the second conductive studs 270 are identical to the conductive studs 150 described in the first embodiment (refer to FIG. 1A). Hence, a detailed description is omitted. Similarly, the shape, the material and the function of the conductive bodies 230 are identical to the conductive bodies 130 in the first embodiment (refer to FIG. 1A) and hence a detailed description is omitted.

### Third Embodiment

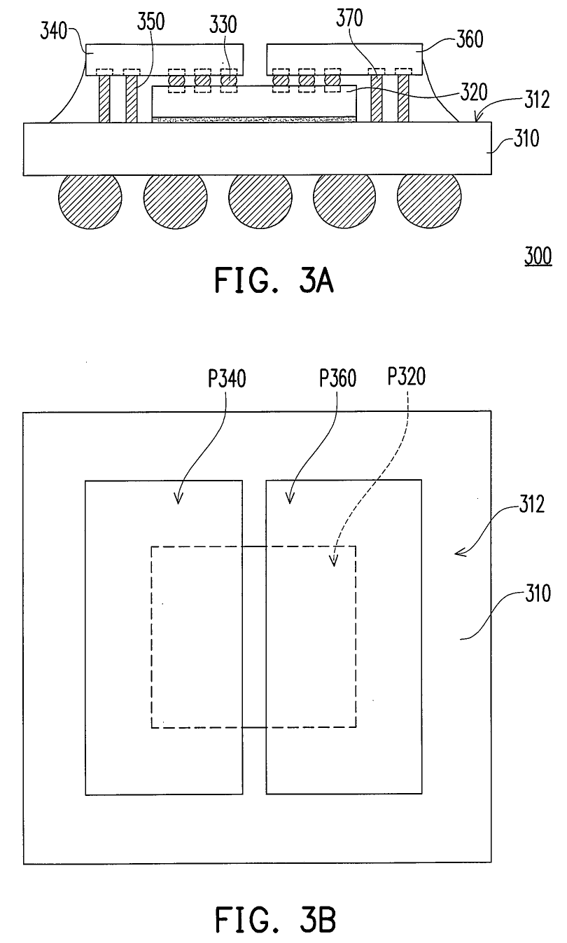

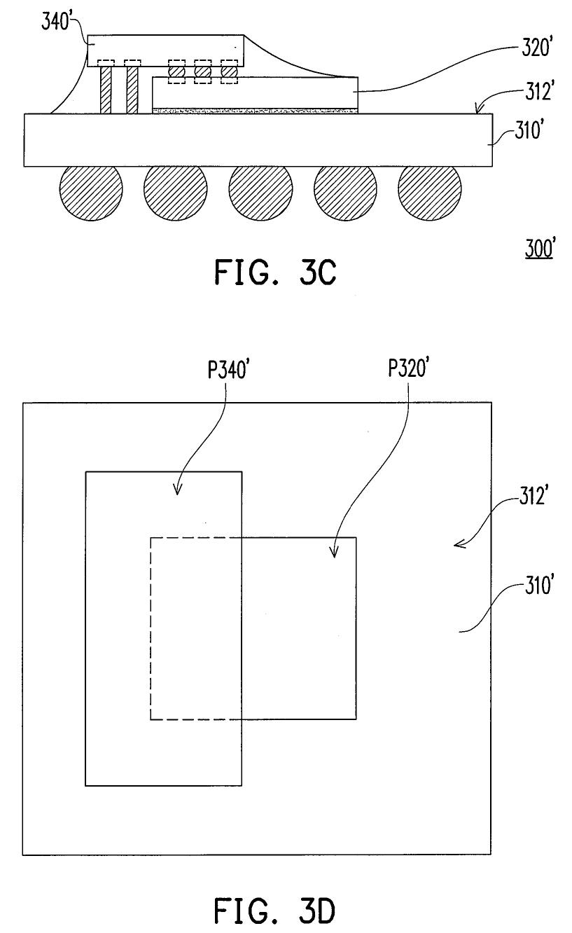

FIG. 3A is a schematic cross-sectional view of a multi-chip package according to a third embodiment of the present invention. FIG. 3B is a diagram showing orthogonal projections of the chips in FIG. 3A on a substrate. As shown in FIGS. 2A, 3A and 3B, the main difference between the multi-chip package 300 in the third embodiment and the multi-chip package 200 in the second embodiment is that the first chip 320, the second chip 340 and the third chip 360 are stacked differently.

More specifically, at least part of the first chip 320 is between the second chip 340 and the substrate 310. Moreover, the first orthogonal projection P320 of the first chip 320 on the first surface 312 of the substrate 310 at least overlaps the second orthogonal projection P340 of the second chip 340 on the first surface 312. In addition, at least part of the first chip 320 is between the third chip 360 and the substrate 310. Moreover, the first orthogonal projection P320 at least overlaps the third orthogonal projection P360 of the third chip 360 on the first surface 312 of the substrate 310.

Part of the conductive bodies 330 are disposed and electrically connected between the first chip 320 and the second chip 340. Furthermore, another part of the conductive bodies 330 are disposed and electrically connected between the first chip 320 and the third chip 360. In addition, the first conductive studs 350 are disposed and electrically connected between the second chip 340 and the first surface 312 of the substrate 210, and the second conductive studs 370 are disposed and electrically connected between the third chip 360 and the first surface 312. The shape, the material and the function of the first conductive studs 350 and the second conductive studs 370 are identical to the conductive studs 150 described in the first embodiment (refer to FIG. 1A). Hence, a detailed description is omitted. Similarly, the shape, the material and the function of the conductive bodies 330 are identical to the conductive bodies 130 in the first embodiment (refer to FIG. 1A) and hence a detailed description is omitted.

FIG. 3C is a schematic cross-sectional view of another multi-chip package according to the third embodiment of the present invention. FIG. 3D is a diagram showing orthogonal projections of the chips in FIG. 3C on a substrate. As shown in FIGS. 3C and 3D, the main difference between the multi-chip package 300′ and the multi-chip package 300 is that the multi-chip package 300′ does not have the third chip 360 (see FIG. 3A). It should be noted that the area of the second orthogonal projection P340′ of the second chip 340′ on the first surface 312′ of the substrate 310′ may be smaller than the area of the first orthogonal projection P320′ of the first chip 320′ on the first surface 312′ of the substrate 310′.

### Fourth Embodiment

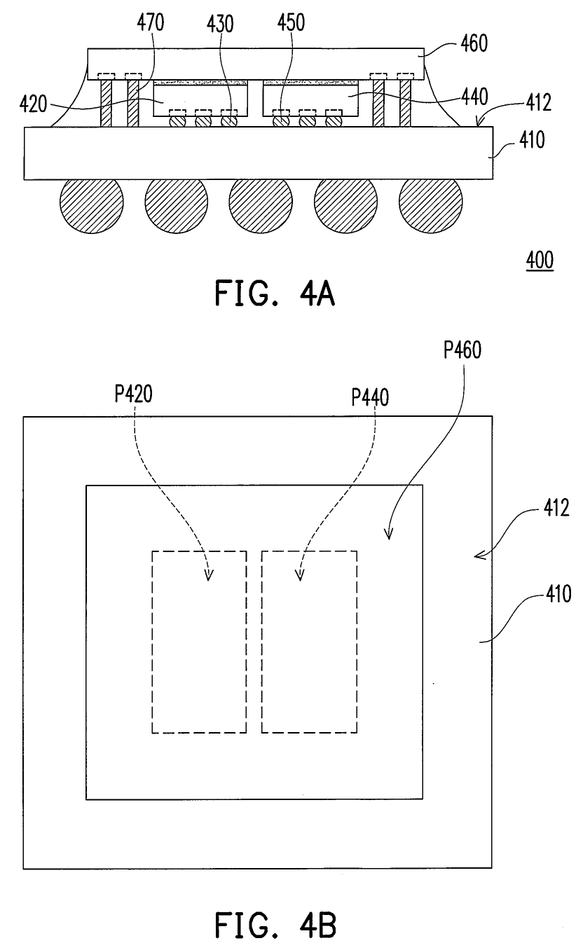

FIG. 4A is a schematic cross-sectional view of a multi-chip package according to a fourth embodiment of the present invention. FIG. 4B is a diagram showing orthogonal projections of the chips in FIG. 4A on a substrate. As shown in FIGS. 2A, 4A and 4B, the main difference between the multi-chip package 400 in the fourth embodiment and the multi-chip package 200 in the second embodiment is that the first chip 420, the second chip 440 and the third chip 460 are stacked differently.

More specifically, the first chip 420 and the second chip 440 are between the third chip 460 and the substrate 410. Moreover, the third orthogonal projection P460 of the third chip 460 on the first surface 412 of the substrate 410 at least overlaps the first orthogonal projection P420 of the first chip 420 on the first surface 412 and the second orthogonal projection P420 of the second chip 440 on the first surface 412. In the fourth embodiment, the first orthogonal projection P420 and the second orthogonal projection P440 are, for example, entirely located within the third orthogonal projection P460. However, the package designers may modify the relative locations of the first chip 420, the second chip 440 and the third chip 460 according to the design requirements as long as the first orthogonal projection P420 at least overlaps the third orthogonal projection P460 and the second orthogonal projection P440 at least overlaps the third orthogonal projection P460.

In the fourth embodiment, the first conductive bodies 430 are disposed and electrically connected between the first chip 420 and the first surface 412 of the substrate 410 and the second conductive bodies 450 are disposed and electrically connected between the second chip 440 and the first surface 412. The conductive studs 470 are disposed and electrically connected between the third chip 460 and the first surface 412. In addition, the shape, the material and the function of the first conductive bodies 430 and the second conductive bodies 450 are identical to the conductive studs 150 described in the first embodiment (refer to FIG. 1A). Hence, a detailed description is omitted. Similarly, the shape, the material and the function of the conductive studs 470 are identical to the conductive studs 150 in the first embodiment (refer to FIG. 1A) and hence a detailed description is omitted.

In summary, the multi-chip package of the present invention at least includes the following: advantages:

1. Because at least one of the chips inside the multi-chip package are electrically connected to the substrate through conductive studs and each conductive stud occupies a very small volume, the areas of the bonding pads on the chip in contact with the corresponding conductive studs can be smaller and the pitch between neighboring bonding pads can be reduced. Therefore, compared with a multi-chip package formed by the conventional technology, the volume of the chip can be smaller when the chip in the multi-chip package of the present embodiment has the same number of bonding pads. As a result, the multi-chip package 100 can occupy a smaller volume.

2. Because the substrate of the multi-chip package may include at least one cavity for accommodating a chip, overall volume of the multi-chip package may be reduced even further.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A multi-chip package, comprising:
a substrate, having a first surface;
a first chip, disposed on the first surface and having a first orthogonal projection on the first surface;
a plurality of conductive bodies, disposed and electrically connected between the first chip and the first surface; a second chip, disposed on the first surface and having a second orthogonal projection on the first surface, wherein at least part of the first chip is between the second chip and the substrate, and the first orthogonal projection at least overlaps the second orthogonal projection; and
a plurality of conductive studs, disposed and electrically connected between the second chip and the first surface.

2. The multi-chip package of claim 1, wherein the substrate comprises a cavity on the first surface, wherein the first chip is located inside the cavity.

3. The multi-chip package of claim 1, wherein a material of the conductive studs is selected from a group comprising copper, aluminum, gold, platinum and titanium or one of the alloys formed by combining at least one of the materials in the group.

4. The multi-chip package of claim 1, wherein the conductive bodies are conductive bumps.

5. The multi-chip package of claim 1, wherein the conductive bumps and the conductive studs have identical shapes.

6. The multi-chip package of claim 5, wherein a material of the conductive bodies is selected from a group comprising copper, aluminum, gold, platinum and titanium or one of the alloys formed by combining at least one of the materials in the group.

7. The multi-chip package of claim 1, further comprising an adhesive layer disposed between the first chip and the second chip.

8. The multi-chip package of claim 1, further comprising an underfill layer that at least encapsulates the conductive bodies and the conductive studs.

9. The multi-chip package of claim 1, further comprising a plurality of solder balls disposed on a second surface of the substrate on the opposite side of the first surface.

10. A multi-chip package, comprising:
a substrate, having a first surface;
a first chip, disposed on the first surface and having a first orthogonal projection on the first surface;
a plurality of conductive bodies, disposed and electrically connected between the first chip and the first surface;
a second chip, disposed on the first surface and having a second orthogonal projection on the first surface, wherein at least part of the first chip is between the second chip and the substrate, and the first orthogonal projection at least overlaps the second orthogonal projection;
a plurality of first conductive studs, disposed and electrically connected between the second chip and the first surface;
a third chip, disposed on the first surface and having a third orthogonal projection on the first surface, wherein at least part of the second chip is between the third chip and the substrate, and the second orthogonal projection at least overlaps the third orthogonal projection; and
a plurality of second conductive studs, disposed and electrically connected between the third chip and the first surface.

11. The multi-chip package of claim 10, wherein the substrate further comprises a cavity on the first surface, wherein the first chip is located inside the cavity.

12. The multi-chip package of claim 10, wherein a material of the first conductive studs is selected from a group comprising copper, aluminum, gold, platinum and titanium or one of the alloys formed by combining at least one of the materials in the group.

13. The multi-chip package of claim 10, wherein a material of the second conductive studs is selected from a group comprising copper, aluminum, gold, platinum and titanium or one of the alloys formed by combining at least one of the materials in the group.

14. The multi-chip package of claim 10, wherein the conductive bodies are conductive bumps.

15. The multi-chip package of claim 10, wherein the conductive bodies has a shape identical to the shape of the first conductive studs or the second conductive studs.

16. The multi-chip package of claim 15, wherein a material of the conductive bodies is selected from a group comprising copper, aluminum, gold, platinum and titanium or one of the alloys formed by combining at least one of the materials in the group.

17. The multi-chip package of claim 10, further comprising a first adhesive layer disposed between the first chip and the second chip.

18. The multi-chip package of claim 10, further comprising a second adhesive layer disposed between the second chip and the third chip.

19. The multi-chip package of claim 10, further comprising an underfill layer that at least encapsulates the conductive bodies, the first conductive studs and the second conductive studs.

20. The multi-chip package of claim 10, further comprising a plurality of solder balls disposed on a second; surface of the substrate on the opposite side of the first surface.

21. A multi-chip package, comprising:
a substrate, having a first surface;
a first chip, disposed on the first surface and having a first orthogonal projection on the first surface;
a second chip, disposed on the first surface and having a second orthogonal projection on the first surface, wherein part of the first chip is between the second chip and the substrate, and the first orthogonal projection at least overlaps the second orthogonal projection;
a plurality of first conductive bodies, disposed and electrically connected between the first chip and the second chip, and
a plurality of first conductive studs, disposed and electrically connected between the second chip and the first surface.

22. The multi-chip package of claim 21, wherein the substrate further comprises a cavity on the first surface, wherein the first chip is located inside the cavity.

23. The multi-chip package of claim 21, wherein a material of the first conductive studs is selected from a group comprising copper, aluminum, gold, platinum and titanium or one of the alloys formed by combining at least one of the materials in the group.

24. The multi-chip package of claim 21, wherein the first conductive bodies are conductive bumps.

25. The multi-chip package of claim 21, wherein the first conductive bodies have a shape identical to the shape of the first conductive studs.

26. The multi-chip package of claim 25, wherein a material of the first conductive bodies is selected from a group comprising copper, aluminum, gold, platinum and titanium or one of the alloys formed by combining at least one of the materials in the group.

27. The multi-chip package of claim 21, further comprising an adhesive layer disposed between the first chip and the substrate.

28. The multi-chip package of claim 21, further comprising an underfill layer that at least encapsulates the first conductive bodies and the first conductive studs.

29. The multi-chip package of claim 21, further comprising a plurality of solder balls disposed on a second surface of the substrate on the opposite side of the first surface.

30. The multi-chip package of claim 21, further comprising:
a third chip, disposed on the first surface and having a third orthogonal projection on the first surface, wherein part of the first chip is between the third chip and the substrate, and the first orthogonal projection at least overlaps the third orthogonal projection;
a plurality of second conductive bodies, disposed and electrically connected between the first chip and the third chip; and
a plurality of second conductive studs, disposed and electrically connected between the third chip and the first surface.

31. The multi-chip package of claim 30, wherein a material of the second conductive studs is selected from a group comprising copper, aluminum, gold, platinum and titanium or one of the alloys formed by combining at least one of the materials in the group.

32. A multi-chip package, comprising:
a substrate, having a first surface;
a first chip, disposed on the first surface and having a first orthogonal projection on the first surface;
a plurality of first conductive bodies, disposed and electrically connected between the first chip and the first surface;
a second chip, disposed on the first surface and having a second orthogonal projection on the first surface;
a plurality of second conductive bodies, disposed and electrically connected between the second chip and the first surface;
a third chip, disposed on the first surface and having a third orthogonal projection on the first surface, wherein the first chip and the second chip are between the third chip and the substrate, and the third orthogonal projection at least overlaps the first orthogonal projection and the second orthogonal projection; and
a plurality of conductive studs, disposed and electrically connected between the third chip and the first surface.

33. The multi-chip package of claim 32, wherein the substrate has two cavities on the first surface, wherein the first and the second chip are located inside the respective cavities.

34. The multi-chip package of claim 32, wherein a material of the conductive studs is selected from a group comprising copper, aluminum, gold, platinum and titanium or one of the alloys formed by combining at least one of the materials in the group.

35. The multi-chip package of claim 32, wherein the first conductive bodies are conductive bumps.

36. The multi-chip package of claim 32, wherein the first conductive bodies have a shape identical to the shape of the conductive studs.

37. The multi-chip package of claim 36, wherein a material of the first conductive bodies is selected from a group comprising copper, aluminum, gold, platinum and titanium or one of the alloys formed by combining at least one of the materials in the group.

38. The multi-chip package of claim 32, wherein the second conductive bodies are conductive bumps.

39. The multi-chip package of claim 32, wherein the second conductive bodies have a shape identical to the shape of the conductive studs.

40. The multi-chip package of claim 39, wherein a material of the second conductive bodies is selected from a group comprising copper, aluminum, gold, platinum and titanium or one of the alloys formed by combining at least one of the materials in the group.

41. The multi-chip package of claim 32, further comprising an adhesive layer disposed between the third chip and the first chip and between the third chip and the second chip.

42. The multi-chip package of claim 32, further comprising an underfill layer that at least encapsulates the first conductive bodies, the second conductive bodies and the conductive studs.

43. The multi-chip package of claim 32, further comprising a plurality of solder balls disposed on a second surface of the substrate on the opposite side of the first surface.
